(19) United States
(12) Patent Application Publication
(10) Pub. No.: US 2007/0193513 A1
(43) Pub. Date: Aug. 23, 2007

(54) Plasma generating method, plasma generating apparatus, and plasma processing apparatus

(75) Inventors: Hiroshige Deguchi, Kyoto (JP); Hitoshi Yoneda, Kyoto (JP); Kenji Kato, Kyoto (JP); Akinori Ebe, Kyoto (JP); Yuichi Setsuhara, Osaka (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignees: NISSIN ION EQUIPMENT CO., LTD.; EMD CORPORATION

(21) Appl. No.: 11/708,058

(22) Filed: Feb. 20, 2007

(30) Foreign Application Priority Data
Feb. 20, 2006 (JP) P.2006-042287

(51) Int. Cl. C23C 16/00

(52) U.S. Cl. 118/723 I

(57) ABSTRACT

A plasma generating method and apparatus which use plural high-frequency antennas 2 to generate inductively coupled plasma, and a plasma processing apparatus using the apparatus. The antennas 2 are identical to one another. Application of a high-frequency electric power to the antennas 2 is performed from a high-frequency power source 4 which is disposed commonly to the antennas 2, through one matching circuit 5 and one busbar 3. The busbar 3 is partitioned into sections the number of which is equal to that of the antennas, while setting a portion which is connected to the matching circuit 5, as a reference. One-end portions of the antennas are connected to corresponding sections 31, 32, 33 through power supplying lines 311, 321, 331. The other end portions of the antennas are grounded. The impedances of the sections of the busbar, and those of the power supplying lines are adjusted so that same currents flow through the antennas, and a same voltage is applied to the antennas. Therefore, the inductively coupled plasma is generated while uniformalizing high-frequency electric powers supplied to the antennas 2.

### TECHNICAL FIELD

The present disclosure relates to a plasma generating method and apparatus for generating gas plasma, and also to a plasma processing apparatus which uses such a plasma generating apparatus, or a plasma processing apparatus which applies a desired process on a workpiece under plasma.

### RELATED ART

For example, plasma is used in a plasma CVD method and apparatus which form a film under plasma, a method and apparatus which sputter a sputter target under plasma to form a film, a plasma etching method and apparatus which perform etching under plasma, a method and apparatus which extract ions from plasma to perform ion implantation or ion doping, and the like. Furthermore, plasma is used in various apparatuses which use the above-mentioned method or apparatus to produce various semiconductor devices (for example, thin film transistors used in a liquid crystal device or the like), material substrates for such semiconductor devices, and the like.

As a method and apparatus for generating gas plasma, various types are known such as those in which capacitively coupled plasma is generated, in which inductively coupled plasma is generated, in which ECR (Electron Cyclotron Resonance) plasma is generated, and in which microwave plasma is generated.

Among the above apparatuses and methods, the method and apparatus for generating plasma in which inductively coupled plasma is generated are configured so that, in order that uniform plasma the density of which is as high as possible is obtained in a plasma generating chamber, a high-frequency antenna is disposed in the plasma generating chamber, and a high-frequency electric power is applied to a gas in the chamber by the high-frequency antenna, thereby generating inductively coupled plasma.

Such a high-frequency antenna is sometimes disposed outside a plasma generating chamber. It has been proposed that a high-frequency antenna is placed in a plasma generating chamber for purposes of, for example, improving the use efficiency of an introduced high-frequency electric power.

Furthermore, it has been proposed to dispose plural high-frequency antennas in a plasma generating chamber for purposes of, for example, forming a thin film on a large-area substrate under plasma, and forming a thin film by one process on plural substrates under plasma.

For example, Japanese Patent Unexamined Publication No. 2001-3174 (Patent Reference 1) discloses a inductively coupled type plasma CVD apparatus in which plural high-frequency antennas are disposed in a plasma generating chamber serving also as a film forming chamber.

In the case where inductively coupled plasma is generated by using plural high-frequency antennas in this way, improvements for generating plasma as uniformly as possible in a plasma generating chamber have been performed.

For example, JP-A-2001-3174 discloses a configuration in which a high-frequency power source and a matching circuit are disposed for each of plural high-frequency antennas so that, when a thin film is to be formed on plural substrates, uniform plasma is generated over a wide range in the plasma generating chamber serving also as a film forming chamber, and a uniform thin film can be formed on the substrates.

Another configuration has been proposed in which power supply is conducted from one high-frequency power source to plural high-frequency antennas through one matching circuit, and a passive device such as a capacitor or reactor circuit is added so that a high-frequency antenna power is evenly supplied to the high-frequency antennas, thereby enabling uniform plasma to be generated over a wide range.

In the case where a high-frequency power source is disposed for each of plural high-frequency antennas as described in JP-A-2001-3174, however, the production cost of a plasma generating apparatus is very high because a high-frequency power source is expensive.

By contrast, when, as in the other proposal, a single high-frequency power source is disposed commonly to plural high-frequency antennas and a passive device such as a capacitor or reactor circuit is added, the production cost is correspondingly low.

In a state where plasma lights, however, the loads of the high-frequency antennas are varied depending on conditions of generating plasma, i.e., the state of plasma (for example, the conductivity of plasma is changed, and therefore the loads of the high-frequency antennas are varied), and the impedances of the antennas are correspondingly changed. Therefore, addition of a passive device cannot cope with such a change, and the power distribution to the high-frequency antennas cannot be sufficiently controlled.

### SUMMARY

Embodiments of the present invention provide a plasma generating method and apparatus which can economically and uniformly generate plasma in the plasma generating chamber.

Embodiments of the present invention provide a plasma processing apparatus in which uniform plasma can be economically generated over a wide range, and a desired process can be applied on a workpiece economically and uniformly under the plasma.

The inventors have conducted researches in order to attain the objects, and noted the following points.

The case where plural high-frequency antennas are disposed in a plasma generating chamber, and a high-frequency electric power is applied to a gas in the plasma generating chamber by the high-frequency antennas, thereby generating inductively coupled plasma will be considered. In order to economically generate plasma, it is preferable to use a power source which is common to plural high-frequency antennas, as a high-frequency power source. A high-frequency power is supplied from the high-frequency power source to the high-frequency antennas through a matching circuit connected to the power source, and a busbar connected to the matching circuit.

In this case, the high-frequency antennas are made identical to one another so that, when plasma lights (when plasma is generated), same currents flow through the antennas, and the same voltage is applied to the antennas. Irrespective of conditions of generating plasma, or in other words changes of the plasma state, therefore, high-frequency powers supplied to the antennas are uniformalized, and uniform plasma can be correspondingly generated in the plasma generating chamber.

In order to allow same currents to flow through the antennas, and the same voltage to be applied to the antennas, the busbar is partitioned in a longitudinal direction of the busbar into sections the number of which is equal to that of the high-frequency antennas, while setting a portion which is connected to the matching circuit, as a reference, one-end portions (power supply end portions) of the high-frequency antennas are connected to the sections through power supplying lines, while respectively corresponding the high-frequency antennas to the sections, the other end portions of the high-frequency antennas are set to a grounded state under the same conditions, and impedances of the sections of the busbar, and those of the power supplying lines through which the high-frequency antennas are connected to the sections are adjusted.

The adjustment of the impedances of the busbar sections is easily performed by, for example, using a strip-shaped busbar as the busbar, and adjusting the lengths, thicknesses, and widths of the sections. In this case, the thickness may be constant.

The impedances of the power supplying lines can be easily adjusted by, for example, changing the lengths of the power supplying lines while maintaining the section shapes and areas of the power supplying lines.

As a result, a high-frequency power is supplied to the high-frequency antennas economically and uniformly irrespective of changes of the antenna impedance in generation of plasma, and uniform plasma can be correspondingly generated in the plasma generating chamber.

According to one or more embodiments of the invention, on the basis of this finding, the method of generating plasma is provided in which plural high-frequency antennas are disposed in a plasma generating chamber, and a high-frequency electric power is applied to a gas in the plasma generating chamber by the high-frequency antennas, thereby generating inductively coupled plasma, wherein identical high-frequency antennas are used as the high-frequency antennas; application of the high-frequency electric power to the high-frequency antennas is performed from a high-frequency power source which is disposed commonly to the high-frequency antennas, through a matching circuit connected to the high-frequency electric power source, and a busbar connected to the matching circuit; the busbar is partitioned in a longitudinal direction of the busbar into sections a number of which is equal to a number of the high-frequency antennas, while setting a portion which is connected to the matching circuit, as a reference; one-end portions of the high-frequency antennas are connected to the sections through power supplying lines, while respectively corresponding the high-frequency antennas to the sections; other end portions of the high-frequency antennas are set to a grounded state under same grounding conditions; the busbar and the power supplying lines are enclosed by a shield case which is at a ground potential; and impedances of the sections of the busbar, and impedances of the power supplying lines through which the high-frequency antennas are connected to the sections are adjusted so that, when plasma is generated, same currents flow through the high-frequency antennas, and a same voltage is applied to the high-frequency antennas, whereby the inductively coupled plasma is generated while uniformalizing high-frequency electric powers supplied to the high-frequency antennas.

According to one or more embodiments of the invention, the apparatus for generating plasma is provided in which plural high-frequency antennas are disposed in a plasma generating chamber, and a high-frequency electric power is applied to a gas in the plasma generating chamber by the high-frequency antennas, thereby generating inductively coupled plasma, wherein the high-frequency antennas are identical to one another; application of the high-frequency electric power to the high-frequency antennas is performed from a high-frequency power source which is disposed commonly to the high-frequency antennas, through a matching circuit connected to the high-frequency electric power source, and a busbar connected to the matching circuit; the busbar is partitioned in a longitudinal direction of the busbar into sections a number of which is equal to a number of the high-frequency antennas, while setting a portion which is connected to the matching circuit, as a reference; one-end portions of the high-frequency antennas are connected to the sections through power supplying lines, while respectively corresponding the high-frequency antennas to the sections; other end portions of the high-frequency antennas are set to a grounded state under same grounding conditions; the busbar and the power supplying lines are enclosed by a shield case which is at a ground potential; and impedances of the sections of the busbar, and impedances of the power supplying lines through which the high-frequency antennas are connected to the sections are adjusted so that, when plasma is generated, same currents flow through the high-frequency antennas, and a same voltage is applied to the high-frequency antennas, whereby the inductively coupled plasma is generated while uniformalizing high-frequency electric powers supplied to the high-frequency antennas.

The terms “a grounded state under same grounding conditions” in “other end portions of the high-frequency antennas are set to a grounded state under same grounding conditions” in the method and apparatus for generating plasma according to the invention mean: a state where the high-frequency antennas are directly connected to a plasma generating chamber which is grounded, whereby the antennas are grounded; that where the high-frequency antennas are connected to the plasma generating chamber in the same manner by using grounding lines which are identical to one another in sectional area, length, material, and the like, whereby the antennas are grounded; that where the high-frequency antennas are directly grounded in the same manner by using grounding lines which are identical to one another in sectional area, length, material, and the like, whereby the antennas are grounded; etc. In summary, the terms mean a state where the high-frequency antennas are set to a grounded state under same grounding conditions.

In both the impedance adjustments in “the adjustment of the impedances of the sections of the busbar” and “impedances of the power supplying lines through which the high-frequency antennas are connected to the sections are adjusted” in the method and apparatus for generating plasma according to the invention, strictly speaking, the internal impedance, the spatial impedance, and the admittance ought to be considered. This consideration may be done. However, the internal impedance and the admittance are smaller than the spatial impedance. Even when both “the adjustment of the impedances of the sections of the busbar” and “impedances of the power supplying lines are adjusted” are performed by adjusting the spatial impedance, therefore, there arises no practical problem.

In both the method and apparatus for generating plasma according to the invention, the followings can be attained.

Plural antennas can be disposed in the plasma generating chamber. When a high-frequency power source which is common to plural high-frequency antennas is used, in the related art, it is difficult to supply economically and uniformly a high-frequency power to the high-frequency antennas irrespective of changes of the antenna impedance in generation of plasma. Particularly, the advantage of applying the invention can be largely attained in the case where three or more high-frequency antennas are used.

As a typical example of places of one-end portions of the high-frequency antennas which are connected to the sections of the busbar, the case may be employed where the one-end portions of the high-frequency antennas are connected to end portions of the busbar sections to which the high-frequency antennas are to be connected, the end portions being remote from the portion to which the matching circuit is connected.

An example in which the impedances of the sections of the busbar can be adjusted in a relatively easy manner is the following configuration.

A strip-shaped busbar is used as the busbar, and the adjustment of the impedances of the busbar sections is performed by adjusting lengths in the longitudinal direction of the busbar, thicknesses, and widths of the busbar sections. The term “adjustment” in the specification includes an adjustment of “the thickness is constant”.

In a strip-shaped busbar, it is often that the width can be changed more easily than the thickness by a cutting process or the like. In order to adjust more easily the impedances of the sections, therefore, the thicknesses of all the sections may be constant.

According to one or more embodiments of the invention, in order to attain the third object, a plasma processing apparatus which applies a desired process on a workpiece under plasma, wherein one of the above-described plasma generating apparatuses according to the invention is used as a plasma source is provided.

The plasma processing apparatus of the invention has advantages that uniform plasma can be economically generated over a wide range, and that a desired process can be applied on a workpiece economically and uniformly under the plasma.

Examples of such a plasma processing apparatus are various apparatus using plasma such as: a plasma CVD apparatus; an apparatus which sputters a sputter target under plasma to form a film; an etching apparatus using plasma; an apparatus which extracts ions from plasma to perform ion implantation or ion doping; and an apparatus which uses the above-mentioned apparatus and produces various semiconductor devices (for example, thin film transistors used in a liquid crystal device or the like), material substrates for such semiconductor devices, and the like.

One or more embodiments of the present invention may include one or more the following advantages. For example, it is possible to provide a method of generating plasma in which plural high-frequency antennas are disposed in a plasma generating chamber, and a high-frequency electric power is applied to a gas in the plasma generating chamber by the high-frequency antennas, thereby generating inductively coupled plasma, wherein a high-frequency power is supplied to the high-frequency antennas economically and uniformly irrespective of changes of the antenna impedance in generation of plasma, and uniform plasma can be correspondingly generated in the plasma generating chamber.

Furthermore, it is possible to provide an apparatus for generating plasma in which plural high-frequency antennas are disposed in a plasma generating chamber, and a high-frequency electric power is applied to a gas in the plasma generating chamber by the high-frequency antennas, thereby generating inductively coupled plasma, wherein a high-frequency power is supplied to the high-frequency antennas economically and uniformly irrespective of changes of the antenna impedance in generation of plasma, and uniform plasma can be correspondingly generated in the plasma generating chamber.

Moreover, it is possible to provide a plasma processing apparatus in which uniform plasma can be economically generated over a wide range, and a desired process can be applied on a workpiece economically and uniformly under the plasma.

Other features and advantages may be apparent from the following detailed description, the accompanying drawings and the claims.

### BRIEF DESCRIPTION OF THE DRAWINGS

FIG. 1 is a diagram showing an example (plasma CVD apparatus) of a plasma processing apparatus that uses an example of a plasma generating apparatus of the invention is used.

FIG. 2 is a diagram extractively showing a high-frequency power source, a matching circuit, a bust bar, high-frequency antennas, and the like of the plasma processing apparatus of FIG. 1.

FIG. 3(A) is a section view of a copper pipe constituting an antenna or the like, and FIG. 3(B) is a section view of a busbar.

FIG. 4 is an equivalent circuit diagram showing a circuit including the busbar, the high-frequency antennas, and the like in the plasma processing apparatus of FIG. 1.

FIG. 5 is a diagram showing another example of main portions of the plasma generating apparatus of the invention.

### DETAILED DESCRIPTION

Hereinafter, one or more embodiments of the invention will be described with reference to the accompanying drawings.

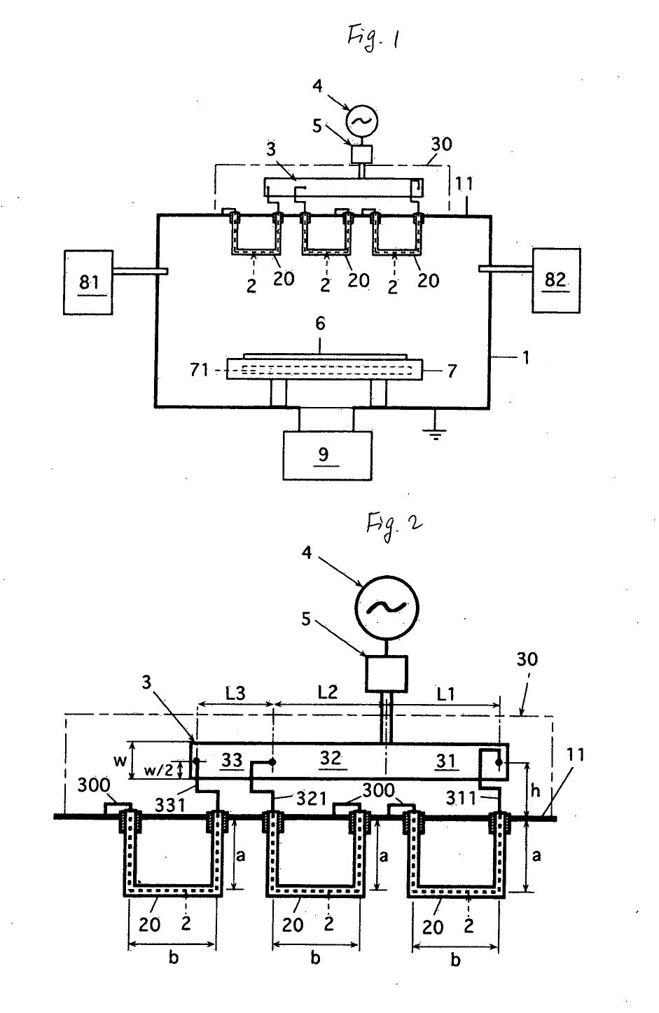

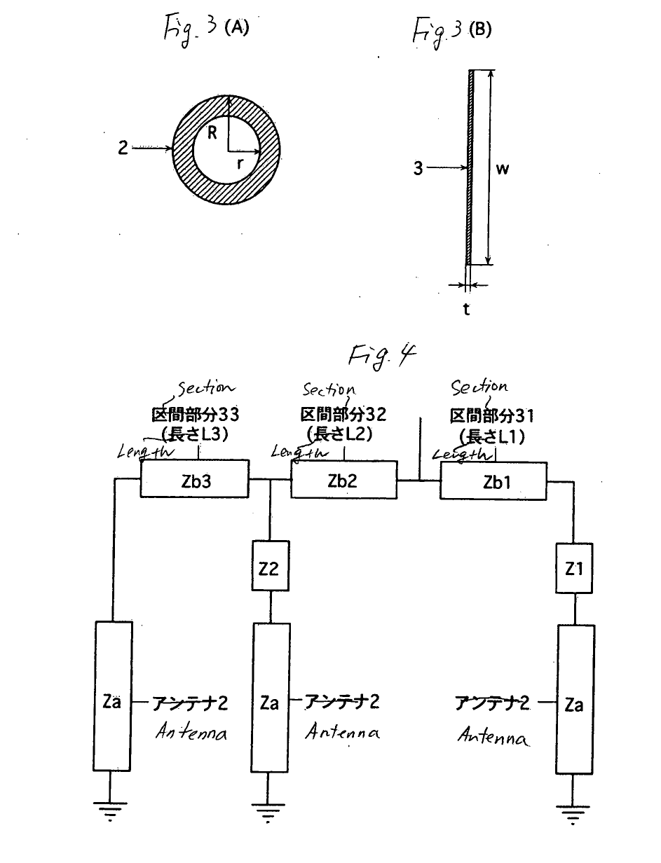

FIG. 1 shows an example (plasma CVD apparatus) of a plasma processing apparatus that uses an example of a plasma generating apparatus in which an example of the plasma generating method of the invention can be executed. FIG. 2 is a diagram extractively showing a high-frequency power source, a matching circuit, a bust bar, high-frequency antennas, and the like of the plasma processing apparatus of FIG. 1.

The plasma processing apparatus of FIG. 1 comprises a film forming chamber 1 serving also as a plasma generating chamber. Three identical high-frequency antennas 2 are hung from a ceiling wall 11 of the film forming chamber 1. Each of the high-frequency antennas 2 is covered by an insulative member 20, and disposed together with the member 20 on the ceiling wall 11.

In this example, the three high-frequency antennas 2 have an inverted portal shape or U-like shape of the same shape and dimensions. As shown in FIG. 2, each of the antennas 2 has a height of a, and a width of b, and, as shown in FIG. 3(A), formed by a copper pipe having an outer peripheral radius of R, an inner peripheral radius of r, and a circular section shape.

One busbar 3 is placed above the ceiling wall 11 of the chamber 1. A high-frequency power source 4 (in the example, a frequency of 13.56 MHz) which is used commonly to the three antennas 2 is connected to the busbar through a matching circuit 5.

The busbar 3 is enclosed by an aluminum-made shield case 30 having a rectangular section shape. The shield case 30 encloses the busbar 3, and is connected to the ceiling wall 11 of the plasma generating chamber 1 to be set to the ground potential.

As shown in FIGS. 2 and 3(B), the busbar 3 is a strip-shaped copper bar in which a section shape is rectangular, and the thickness t and the width w in the vertical direction are constant. The whole of the busbar is partitioned into three sections 31, 32, 33. However, the three sections 31, 32, 33 are not divided from one another, but are integrally continuous to one another. The lengths of the sections in the longitudinal direction of the busbar, i.e., the length L1 of the section 31, the length L2 of the section 32, and the length L3 of the section 33 are set so that the sections 31 and 32 have the same length (L1=L2), and the length L3 of the section 33 is shorter than the lengths (L3<L1, L2).

The matching circuit 5 is connected to an interface portion between the sections 31 and 32.

The antennas 2 are connected at their one-end portions (power supply end portions) to the end portions of the sections 31, 32, 33 which are remote from the matching circuit 5, respectively. More specifically, the antenna 2 for the section 31 is connected by a power supplying line 311, the antenna 2 for the section 32 is connected by a power supplying line 321, and the antenna 2 for the section 33 is connected by a power supplying line 331.

The other end portions of the antennas 2 are connected to the grounded chamber 1 by the same grounding lines (grounding lines which are identical to one another in section shape, length, material, etc.) 300. Namely, the antennas 2 are set to a grounded state under the same grounding conditions.

The power supplying lines 311 to 331 and the grounding lines 300 are formed by copper pipes which are identical with the antennas 2 except the length, and integrally continuous to the antennas 2, respectively.

Also the power supplying lines 311, 321, 331 and the grounding lines 300 are enclosed by the shield case 30.

A substrate holder 7 on which a substrate 6 is to be mounted is placed in the chamber 1. The holder 7 has a heater 7 which can heat the substrate 6 mounted on the holder. The holder 7 and the chamber 1 are grounded.

Gas supplying portions 81, 82 supply predetermined gasses into the chamber 1, respectively. In the example, the gas supplying portion 81 supplies monosilane gas into the chamber 1, and the gas supplying portion 82 supplies hydrogen gas so that a silicon thin film can be formed on the substrate 6.

Also an evacuating apparatus 9 which evacuates the interior of the chamber 1 to set the interior of the chamber 1 to a predetermined reduced pressure state is connected to the chamber 1.

The above-described components such as the chamber 1 serving also as the plasma generating chamber, the antennas 2, the busbar 3, the high-frequency power source 4, the matching circuit 5, the power supplying lines 311 to 331 and grounding lines 300 for the antennas 2, the gas supplying portions 81, 82, and the evacuating apparatus 9 constitute the plasma generating apparatus.

The plasma generating apparatus will be described later in detail.

In the above-described plasma producing apparatus, a gate (not shown) of the chamber 1 is opened, the substrate 6 is placed on the holder 7, the gate is then gas-tightly closed, and, in this state, the interior of the chamber 1 is evacuated by the evacuating apparatus 9 to a pressure which is lower than a predetermined film forming pressure. On the other hand, the substrate 6 is heated as required by the heater 71 toward a predetermined film forming temperature, and the high-frequency power is supplied to the antennas 2 while predetermined amounts of silane and hydrogen gasses are supplied from the gas supplying portions 81, 82 into the chamber 1, and the internal pressure of the chamber 1 is maintained to the predetermined film forming pressure by the evacuating apparatus 9, whereby inductively coupled plasma is generated in the chamber 1. As a result, a silicon thin film can be formed on the substrate 6 under the plasma.

The portions of the plasma generating apparatus will be again described.

The plasma generating apparatus of the example is improved so that, in plasma generation, the high-frequency power is evenly distributingly supplied to the antennas 2, whereby plasma is generated as uniformly as possible in the chamber 1, and a silicon thin film is uniformly formed on the substrate 6.

Specifically, the impedances of the sections of the busbar, and those of the power supplying lines are adjusted so that the same currents (currents which are identical in level and phase) flow through the antennas 2, and the same voltage is applied to the antennas, whereby, in plasma generation, the high-frequency power is evenly distributingly supplied to the antennas 2. In the example, adjustments of the impedances of the sections of the busbar, and those of the power supplying lines are performed by adjusting the spatial impedance which is larger than the internal impedance and the admittance.

FIG. 4 is a diagram showing a circuit including the busbar 3, the power supplying lines 311 to 331, and the antennas 2 in an equivalent circuit manner.

In FIG. 4, Zb1 denotes the spatial impedance of the busbar section 31, Zb2 denotes the spatial impedance of the busbar section 32, and Zb3 denotes the spatial impedance of the busbar section 33. Z1 denotes the spatial impedance of a length portion of the power supplying line 311 which is obtained by subtracting the length of the power supplying line 331 that is shortest, from the length of the line 311, i.e., a portion which is further prolonged with respect to the length of the line 331. Z2 denotes the spatial impedance of a length portion of the power supplying line 321 which is obtained by subtracting the length of the power supplying line 331 that is shortest, from the length of the line 321, i.e., a portion which is further prolonged with respect to the length of the line 331.

Za denotes the impedances of the high-frequency antennas 2 in plasma generation which are equal to one another.

In the circuit of FIG. 4, the current which flows during lighting of plasma through the antenna 2 connected to the busbar section 31 is indicated by I₁, that which flows through the antenna 2 connected to the busbar section 32 is indicated by I₂, and that which flows through the antenna 2 connected to the busbar section 33 is indicated by I₃. It is assumed that the same currents (currents which are identical in level and phase) flow through the antennas 2. When the voltage applied to the antennas 2 at this time is indicated by V, the following expression must hold.

$$\vert \begin{matrix}( Zb 1 + Z 1 ) & 0 & 0 \\ 0 & ( Zb 2 + Z 2 ) & Zb 2 \\ 0 & Zb 2 & ( Zb 2 + Zb 3 )\end{matrix} \vert \vert \begin{matrix}{I}_{1} \\ {I}_{2} \\ {I}_{3}\end{matrix} \vert = \vert \begin{matrix}V \\ V \\ V\end{matrix} \vert \qquad [ Exp . 1 ]$$

The above expression is linear, and hence can be normalized to set I₁=I₂=I₃=1.

Therefore, the relationship of (Zb1+Z1)=(Zb2+Z2)+(Zb2)=(Zb2)+(Zb2+Zb3) must hold.

In other words, when the impedances Zb1 to Zb3, Z1, Z2 are determined so as to satisfy the expression, the high-frequency power can be evenly distributingly supplied to the antennas 2. The impedances of the antennas do not exist in the expression. As far as the impedances of the antennas are changed together in the same manner, therefore, the high-frequency power can be evenly distributingly supplied to the antennas 2 irrespective changes of the plasma state in generation of plasma.

Although not restricted, in the example, settings are performed so that the thickness t of the busbar 3=2 mm, the vertical width w=9 cm, the length L1 of the busbar section 31=the length L2 of the busbar section 32=23 cm, and the length L3 of the busbar section 33=15 cm.

The shield case 30 surrounding the busbar 3 is a box member which has a rectangular section shape, and in which the internal dimension in the same direction as the thickness t of the busbar 3 is 15 cm, and that in the same direction as the width w is 18 cm.

The spatial impedance per unit length of the busbar 3 is about j22 Ω/m.

Therefore, the impedances can be deemed to have the following values:

the impedance Zb1 of the busbar section 31=j5Ω;

the impedance Zb2 of the busbar section 32=j5Ω; and

the impedance Zb3 of the busbar section 33=j3Ω.

As described above, the antennas 2, the power supplying lines 311 to 331 which are integrally continuous to the antennas, and the grounding lines 300 are formed by copper pipes, respectively. Although not restricted, in the example, the pipes are set so that the outer peripheral radius R=2.5 mm and the inner peripheral radius r=1.5 mm. Although not restricted, in the example, the dimensions of the high-frequency antennas 2 in the plasma generating chamber 1 are set so that the height a=10 cm, the width b=15 cm, and the whole length=35 cm.

In the example, the height h from the plasma generating chamber 1 to the connection positions where the power supplying lines (copper pipes) 311 to 331 are connected to the busbar 3 is set to 10 cm.

The spatial impedance per unit length of the copper pipes is about j75 Ω/m.

As described above, in order to uniformalize the currents flowing through the antennas 2 and uniformly supply a power to the antennas, the relationship of

(Zb1+Z1)=(Zb2+Z2)+(Zb2)=(Zb2)+(Zb2+Zb3) must hold.

Namely, j5+Z1=j10+Z2=j13 must be set.

Therefore, Z1=j8Ω, and Z2=j3Ω are attained.

As described above, Z1=j8Ω is the impedance of the portion which, in the power supplying line 311 formed by a copper pipe that is identical with the antennas, is prolonged with respect to the shortest power supplying line 331. Since the impedance per unit length of the copper pipe is j75 Ω/m, the prolonged portion can be set to have a length of 11 cm, or in other words the length of the line 311 can be made longer by 11 cm than that of the line 331.

As described above, Z2=j3Ω is the impedance of the portion which, in the power supplying line 321, is prolonged with respect to the shortest power supplying line 331. When similar calculation is conducted, therefore, the prolonged portion can be set to have a length of 4 cm, or in other words the length of the line 321 can be made longer by 4 cm than that of the line 331.

The power supplying line 311 which is shown in FIGS. 1 and 2, and through which the busbar section 31 is connected to the antenna 2 is longer by 11 cm than the power supplying line 331 through which the section 33 is connected to the antenna 2. The power supplying line 321 through which the busbar section 32 is connected to the antenna 2 is longer by 4 cm than the power supplying line 331.

In the apparatus shown in FIG. 1, as a result, the high-frequency power is evenly supplied to the antennas 2 in plasma generation, and plasma can be generated in a correspondingly uniform manner.

In the above-described example, the busbar 3 has the constant thickness t and vertical width w, and the lengths of the power supplying lines 311, 321 are adjusted with respect to the length of the power supplying line 331. Alternatively, the impedances of the sections of the busbar 3 may be further adjusted.

For example, the case where the whole busbar is formed by a copper bar in the same manner as described above, and, in the busbar sections 32, 33, the thickness t=2 mm and the vertical width w=9 cm, and, in the section 31, the thickness t=2 mm and the vertical width w′=3 cm will be described.

In this case, the spatial impedance per unit length of each of the sections 32, 33 is j22 Ω/m in the same manner as the above-described busbar, and the spatial impedance per unit length of the busbar section 31 having the width w′=3 cm is j40 Ω/m.

Therefore, the impedances can be deemed to have the following values:

the impedance Zb1 of the busbar section 31 having the length L1=23 cm, Zb1=j9Ω;

the impedance Zb2 of the busbar section 32 having the length L2=23 cm, Zb2=j5Ω; and

the impedance Zb3 of the busbar section 33 having the length L3=15 cm, Zb3=j3Ω.

In the same manner as described above, a copper pipe having an impedance per unit length of j75 Ω/m is used as the power supplying lines.

As described above, in order to uniformalize the currents flowing through the antennas 2 and uniformly supply a power to the antennas, the relationship of

(Zb1+Z1)=(Zb2+Z2)+(Zb2)=(Zb2)+(Zb2+Zb3) must hold.

In this case, namely, j9+Z1=j10+Z2=j13 must be set.

Therefore, Z1=j4Ω, and Z2=j3Ω are attained.

Z1=j4Ω is the impedance of the portion which, in the power supplying line 311, is prolonged with respect to the shortest power supplying line 331. Since the impedance per unit length of the copper pipes is j75 Ω/m, the prolonged portion can be set to have a length of 5 cm, or in other words the length of the line 311 can be made longer by 5 cm than that of the line 331.

Z2=j3Ω is the impedance of the portion which, in the power supplying line 321, is prolonged with respect to the shortest power supplying line 331. When similar calculation is conducted, therefore, the prolonged portion can be set to have a length of 4 cm, or in other words the length of the line 321 can be made longer by 4 cm than that of the line 331.

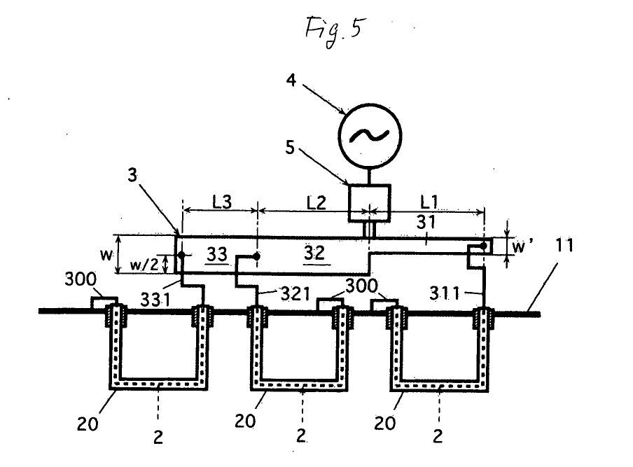

FIG. 5 shows an example where the width w′ of the busbar section 31 is 3 cm, the widths w of the sections 32, 33 are 9 cm, the power supplying line 311 through which the section 31 is connected to the antenna 2 is longer by 5 cm than the power supplying line 331 through which the section 33 is connected to the antenna 2, and the power supplying line 321 through which the section 32 is connected to the antenna 2 is longer by 4 cm than the power supplying line 331. Also in this configuration, the high-frequency power is evenly supplied to the antennas 2 in plasma generation, and plasma can be generated in a correspondingly uniform manner.

The spatial impedance per unit length (1 m) of the busbar can be obtained by an expression of (jωμ₀/2Π)×ln(r3/r2) in Expression 3.38 described in “Bunpu Josu Kairo Ron” (written by AMATANI Akihiro under the supervision of SEKINE Yasuji), KORONASHA, Jan. 20, 1998, p. 70.

In the expression, μ₀ is the magnetic permeability of vacuum (4Π×10⁻⁷), and ω is the angular frequency of the high-frequency power to be applied. Therefore, ω/2Π is the frequency (in the example, 13.56 MHz) of the high-frequency power.

When a conductor having an arbitrary section is approximated by a hollow circular conductor, r2 is the outer radius (equivalent radius) of the hollow circular conductor (r2 [m]). By the following expression described in Expression 3.33 of p. 67 of the above literature or “Bunpu Josu Kairo Ron”, r2 can be obtained:

r2=outer peripheral length of conductor L/2Π [m]

On the other hand, r3 is an equivalent radius of the space extending to a ground potential conductor surrounding the above-mentioned conductor, and can be obtained from Expression 3.33 of p. 67 of “Bunpu Josu Kairo Ron” as the following expression:

r3=inner peripheral length of ground potential conductor/2Π [m]

For example, the spatial impedance Z per unit length (1 m) of the busbar 3 shown in FIGS. 2 and 3B (the thickness t=2 mm=0.2×10⁻² m, the width w=9 cm=9×10⁻² m) can be calculated in the following manner.

Outer peripheral length L of busbar=(0.2×10⁻² m+9×10⁻² m)×2=18.4×10⁻² m

When the busbar is approximated by a bar having a circular section,

outer radius of circular bar r2=L/2Π=18.4×10⁻² m/2×Π≈2.93×10⁻² m.

By contrast, the inner peripheral length L′ of the shield case 30 surrounding the busbar 3 is L′=(15+18)×2×1⁻² m=66×10⁻² m.

Equivalent radius r3 of shield case 30=66×10⁻² m/2Π=10.5×10⁻² m

Therefore, the impedance Z of the busbar 3 is

$$\begin{matrix}Z = ( {jωμ}_{0} / 2 Π ) \times ln ( r 3 / r 2 ) \\ = j f {μ}_{0} \times ln ( r 3 / r 2 ) \\ = j \times 13.56 \times {μ}_{0} \times ln ( 10.5 / 2.93 ) \\ \approx j 22 Ω \text{/} m .\end{matrix}$$

The spatial impedance Z per unit length (1 m) of the copper pipe (outer radius R=0.25×10⁻² m) which constitutes the power supplying lines can be calculated in the following manner.

In this case, r2 in the above impedance calculation expression is R=0.25×10⁻² m, and r3 is 2×h=2×10×10⁻² m.

In this example, the length of a power supplying line, and the equivalent radius of the shield case are dimensions which are approximate in structure (about 10 cm).

The impedance calculation expression which is used in the example is an approximate expression which is an expression in the case where the length of the line is sufficiently longer than the equivalent radius, and in which the effect of the leakage magnetic field due to the end portion of the line is not considered. In the calculation of the impedance of the power supplying line, however, also the effect of the end portion is considered, and hence the impedance is calculated while the equivalent radius is provided with two times the coefficient (the above-described 2×h).

Therefore, the impedance Z of the copper pipe is

$$\begin{matrix}Z = ( {jωμ}_{0} / 2 Π ) \times ln ( 2 h / R ) \\ = j \times 13.56 \times {μ}_{0} \times ln ( 20 / 0.25 ) \\ \approx j 75 Ω \text{/} m .\end{matrix}$$

The invention can be used in various fields in which a desired process is applied on a workpiece under plasma.

What is claimed is:

1. A plasma generating method of generating inductively coupled plasma by applying a high-frequency electric power to a gas in a plasma generating chamber by high-frequency antennas disposed in the plasma generating chamber,
wherein identical high-frequency antennas are used as said high-frequency antennas; application of the high-frequency electric power to said high-frequency antennas is performed from a high-frequency power source which is disposed commonly to said high-frequency antennas, through a matching circuit connected to said high-frequency electric power source, and a busbar connected to said matching circuit; said busbar is partitioned in a longitudinal direction of said busbar into sections a number of which is equal to a number of said high-frequency antennas, while setting a portion which is connected to said matching circuit, as a reference; one-end portions of said high-frequency antennas are connected to said sections through power supplying lines, while respectively corresponding said high-frequency antennas to said sections; other end portions of said high-frequency antennas are set to a grounded state under same grounding conditions; said busbar and said power supplying lines are enclosed by a shield case which is at a ground potential; and impedances of said sections of said busbar, and impedances of said power supplying lines through which said high-frequency antennas are connected to said sections are adjusted so that, when plasma is generated, same currents flow through said high-frequency antennas, and a same voltage is applied to said high-frequency antennas, whereby the inductively coupled plasma is generated while uniformalizing high-frequency electric powers supplied to said high-frequency antennas.

2. A plasma generating method according to claim 1, wherein the number of said high-frequency antennas is three or more.

3. A plasma generating method according to claim 1, wherein said one-end portions of said high-frequency antennas are connected to end portions of said sections of said busbar to which said high-frequency antennas are to be connected, said end portions being remote from said portion to which said matching circuit is connected.

4. A plasma generating method according to claim 1, wherein a strip-shaped busbar is used as said busbar, and the adjustment of the impedances of said sections of said busbar is performed by adjusting lengths in the longitudinal direction of said busbar, thicknesses, and widths of said sections of said busbar.

5. A plasma generating method according to claim 4, wherein the adjustment of the impedances of said sections of said busbar is performed while setting the thicknesses of said sections to be constant.

6. A plasma generating apparatus comprising:
a plasma generating chamber;
plural high-frequency antennas, which are disposed in the plasma generating chamber and apply a high-frequency electric power to a gas in said plasma generating chamber, said high-frequency antennas being identical to one another;
a high-frequency power source, which is disposed commonly to said high-frequency antennas and applies the high-frequency electric power to said high-frequency antennas;
a matching circuit connected to said high-frequency power source;
a busbar connected to said matching circuit, said busbar being partitioned in a longitudinal direction of said busbar into sections a number of which is equal to a number of said high-frequency antennas, while setting a portion of said busbar, which is connected to said matching circuit, as a reference;
power supplying lines connecting one-end portions of said high-frequency antennas to said corresponding sections of said busbar; and
a shield case, which is at a ground potential and encloses said busbar and said power supplying lines,
wherein other end portions of said high-frequency antennas are set to a grounded state under same grounding conditions,
wherein impedances of said sections of said busbar, and impedances of said power supplying lines are adjusted so that, when plasma is generated, same currents flow through said high-frequency antennas, and a same voltage is applied to said high-frequency antennas.

7. A plasma generating apparatus according to claim 6, wherein the number of said high-frequency antennas is three or more.

8. A plasma generating apparatus according to claim 6, wherein said one-end portions of said high-frequency antennas are connected to end portions of said sections of said busbar, said end portions being remote from said portion to which said matching circuit is connected.

9. A plasma generating apparatus according to claim 6, wherein a strip-shaped busbar is used as said busbar, and the adjustment of the impedances of said sections of said busbar is performed by adjusting lengths in the longitudinal direction of said busbar, thicknesses, and widths of said sections of said busbar.

10. A plasma generating apparatus according to claim 9, wherein the adjustment of the impedances of said sections of said busbar is performed while setting the thicknesses of said sections to be constant.

11. A plasma processing apparatus which applies a desired process on a workpiece under plasma, comprising a plasma generating apparatus according to claim 6, as a plasma source.

12. A plasma generating method performed in a plasma generating apparatus according to claim 6, said method comprising a step of:
adjusting impedances of the sections of the busbar, and impedances of the power supplying lines so that, when plasma is generated, same currents flow through said high-frequency antennas, and a same voltage is applied to said high-frequency antennas.

13. A plasma generating method according to claim 12, wherein a strip-shaped busbar is used as said busbar, and the adjustment of the impedances of said sections of said busbar is performed by adjusting lengths in the longitudinal direction of said busbar, thicknesses, and widths of said sections of said busbar.

14. A plasma generating method according to claim 13, wherein the adjustment of the impedances of said sections of said busbar is performed while setting the thicknesses of said sections to be constant.
